(19) United States
(12) Patent Application Publication
(10) Pub. No.: US 2025/0338454 A1
(43) Pub. Date: Oct. 30, 2025

(54) CONFIGURABLE LIQUID MANIFOLD FOR SERVER RACK

(71) Applicant: ZT Group Int'l, Inc., Secaucus, NJ (US)

(72) Inventors: Sruti CHIGULLAPALLI, Seattle, WA (US); Paul Harold ANDERSON, Leander, TX (US); Pruthvik RAGHUPATHI, Seattle, WA (US)

(73) Assignee: ZT Group Int'l, Inc., Secaucus, NJ (US)

(21) Appl. No.: 18/644,533

(22) Filed: Apr. 24, 2024

(51) Int. Cl. H05K 7/20; G06F 1/20

(52) U.S. Cl. CPC H05K 7/20781; G06F 1/20

(57) ABSTRACT

The manifold includes a first portion including first liquid connectors arranged in a first linear array parallel to a longitudinal axis of the first portion. The manifold also includes a second portion including second liquid connectors arranged in a second linear array parallel to a longitudinal axis of the second portion and third liquid connectors arranged in a third linear array parallel to the second longitudinal axis and on a different side of the second portion than the second liquid connectors. The manifold also includes a fitting connecting the first portion and the second portion that allows relative rotation about a rotation axis that is parallel to the longitudinal axes. The first and second liquid connectors may be used for a first width of servers and the third liquid connectors may be used for a second width of servers.

### FIELD

This disclosure is directed to providing liquid to and from a plurality of computing devices within a server rack.

### BACKGROUND

Server racks often contain many servers (e.g., computers, servers, network servers, web servers, artificial intelligence (AI) servers, blades, or switches) that are liquid-cooled. When all of the servers within a rack that require liquid cooling are a similar size, a pair of liquid manifolds, each with a plurality of liquid connectors disposed in a linear array, are often used as influent and effluent plumbing for the servers. Liquid-cooled servers are not limited to a single size, however. For example, many liquid-cooled servers come in 21 inch and 19 inch sizes (nominal). Creating influent and effluent plumbing for racks that contain multiple sizes of servers is difficult.

### SUMMARY

A liquid manifold is described for providing a liquid to or from a plurality of servers within a server rack. The liquid manifold includes a first portion including a first tubular body having a first cavity that extends along a first longitudinal axis and a first external surface. The first portion also includes a plurality of first liquid connectors disposed on the first external surface, communicating with the first cavity, and arranged in a first linear array parallel to the first longitudinal axis. The liquid manifold also includes a second portion including a second tubular body having a second cavity that extends along a second longitudinal axis, a second external surface, and a third external surface. The second portion also includes a plurality of second liquid connectors disposed on the second external surface, communicating with the second cavity, and arranged in a second linear array parallel to the second longitudinal axis. The second portion further includes a plurality of third liquid connectors disposed on the third external surface, communicating with the second cavity, and arranged in a third linear array parallel to the second longitudinal axis. The liquid manifold further includes a first rotating fitting connecting the first portion and the second portion such that the first longitudinal axis is parallel to the second longitudinal axis. The first rotating fitting is configured to allow relative rotation between the first portion and the second portion about a first rotation axis of the first rotating fitting that is parallel to the first longitudinal axis and the second longitudinal axis.

A system for providing influent and effluent flows to a plurality of servers within a rack is also described herein. The system includes a first liquid manifold for providing a liquid to the plurality of servers and a second liquid manifold for providing the liquid from the plurality of servers. Each of the liquid manifolds is configured according to the liquid manifold described above. The system is configurable such that, in a first configuration of the liquid manifolds, the liquid manifolds may, when mounted to the rack, interface with a plurality of similar sized servers and, in a second configuration of the liquid manifolds, the liquid manifolds may, when mounted to the rack, interface with a plurality of first sized servers and a plurality of second sized servers.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIGS. 1A and 1B illustrate examples of server racks that a liquid manifold, in accordance with this disclosure, may interface with.

FIGS. 2A and 2B illustrate examples of a liquid manifold in accordance with this disclosure.

FIG. 3 illustrates an example of a rotating fitting in accordance with this disclosure.

FIGS. 4A and 4B illustrate an example of a system of two liquid manifolds, in accordance with this disclosure, in two configurations.

FIGS. 5A and 5B illustrate an example of a liquid manifold, in accordance with this disclosure, in two configurations.

### DETAILED DESCRIPTION

### Overview

Liquid-cooled servers are not limited to a single size. For example, many liquid-cooled servers (e.g., switch servers or switches) come in 21 inch and 19 inch nominal sizes. Different sizes of servers often cause problems for influent and effluent plumbing of racks when sizes are changed and/or when different sizes are used within a rack. Often times, single-application (e.g., a single size or mixed size) manifolds are fabricated. If the sizes of the servers within the rack change, new manifolds are often fabricated, which is expensive and time consuming.

Described herein is a configurable manifold for providing liquid to or from a plurality of similar or different width servers of a server rack. The manifold includes a first portion including first liquid connectors arranged in a first linear array parallel to a longitudinal axis of the first portion. The manifold also includes a second portion including second liquid connectors arranged in a second linear array parallel to a longitudinal axis of the second portion and third liquid connectors arranged in a third linear array parallel to the second longitudinal axis and on a different side of the second portion than the second liquid connectors. The manifold also includes a fitting connecting the first portion and the second portion that allows relative rotation about a rotation axis that is parallel to the longitudinal axes.

Two liquid manifolds may be used in conjunction to form a system for a rack. For example, a first liquid manifold may be configured as an influent feed for a plurality of servers within the rack and a second liquid manifold may be configured as an effluent feed for the servers.

The liquid manifolds are configurable (via the rotating fittings) in a first configuration where the first liquid connectors are colinear with the second liquid connectors such that the first and second portions of the liquid manifolds may interface with first width servers. Alternatively, the liquid manifolds are configurable (via the rotating fittings) in a second configuration where the third liquid connectors and the first liquid connectors are in parallel planes but offset in a dimension such that the first portions of the liquid manifolds may interface with first width servers and the second portions of the liquid manifolds may interface with second width servers. For example, the first configuration may allow the liquid manifolds to interface with 21 inch servers within the rack while the second configuration may allow the liquid manifolds to interface with 21 inch and 19 inch servers within the rack. In each configuration, liquid connectors that are not being used may be plugged.

By using configurable liquid manifolds, a single design of a manifold may be used for a variety of applications and may adapt to changes in compositions of servers within a rack. Doing so not only saves cost, but also fabrication and installation time compared to multiple designs and/or new manifolds as things change.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Server Racks

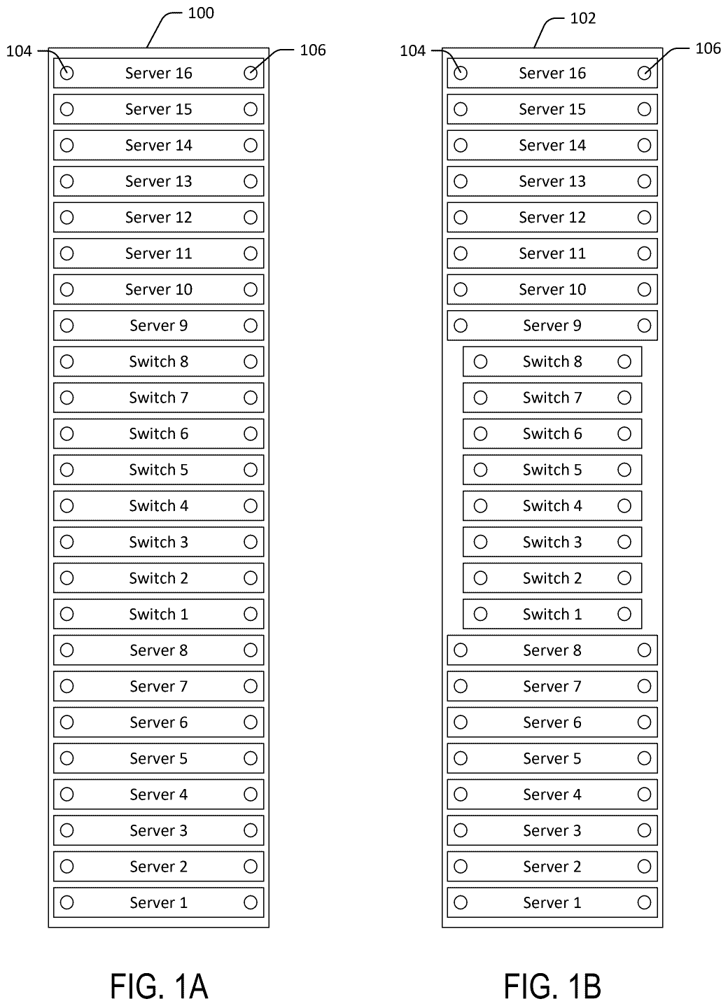

FIGS. 1A and 1B illustrate examples of server racks that a liquid manifold, in accordance with this disclosure, may interface with. FIG. 1A illustrates a server rack 100, and FIG. 1B illustrates a server rack 102. The server rack 100 and the server rack 102 both contain 16 computing servers (e.g., servers 1-8 and 9-16) and 8 switch servers (e.g., switches 1-8). The servers may be any type of computing device (e.g., computers, servers, network servers, web servers, artificial intelligence (AI) servers, blades, or switches), and the 16 computing servers and 8 switch servers are used as an example. The 8 switch servers of server rack 100 are the same width as the 16 computing servers, while the 8 switch servers of server rack 102 thinner (e.g., less wide) than the 16 computing servers. For example, the server rack 100 may have all 21 inch servers (e.g., the computing and switch servers are both 21 inch) while the server rack 102 may have 16 servers that are 21 inch servers and 8 servers that are 19 inch servers (e.g., the computing servers are 21 inch and the switch servers are 19 inch). Although the switch servers are shown as having two width configurations (e.g., 21 and 19 inch), the computing servers (or any other servers) may also be configured with the two widths.

The numbers and configurations of the servers may vary without departing from the scope of this disclosure. For example, the widths, numbers of each type (e.g., computing, switch, or other servers), total numbers of servers within a rack, or numbers of each width server may vary. Furthermore, although the server rack 102 is shown with blocks of wider servers surrounding the thinner servers, the blocks may be fully separated (e.g., all the computing servers together above or below the switch servers).

Within each of the servers are an influent port 104 and an effluent port 106. In the server rack 100, because the servers are all the same width, the influent ports 104 may be aligned vertically (e.g., in a linear array) and the effluent ports 106 may be aligned vertically (e.g., in a linear array). Accordingly, straight manifolds may be used for the set of influent ports 104 and the set of effluent ports 106 in the server rack 100.

However, in the server rack 102, because the servers have different widths, the influent ports 104 and the effluent ports 106 may be inbound of those of the computing servers. Accordingly, straight manifolds may not be used for the set of influent ports 104 and the set of effluent ports 106 in server rack 102. Configurable liquid manifolds in accordance with this disclosure, however, can interface with the influent ports 104 and the effluent ports 106 on both server rack 100 and server rack 102.

### Example Liquid Manifold

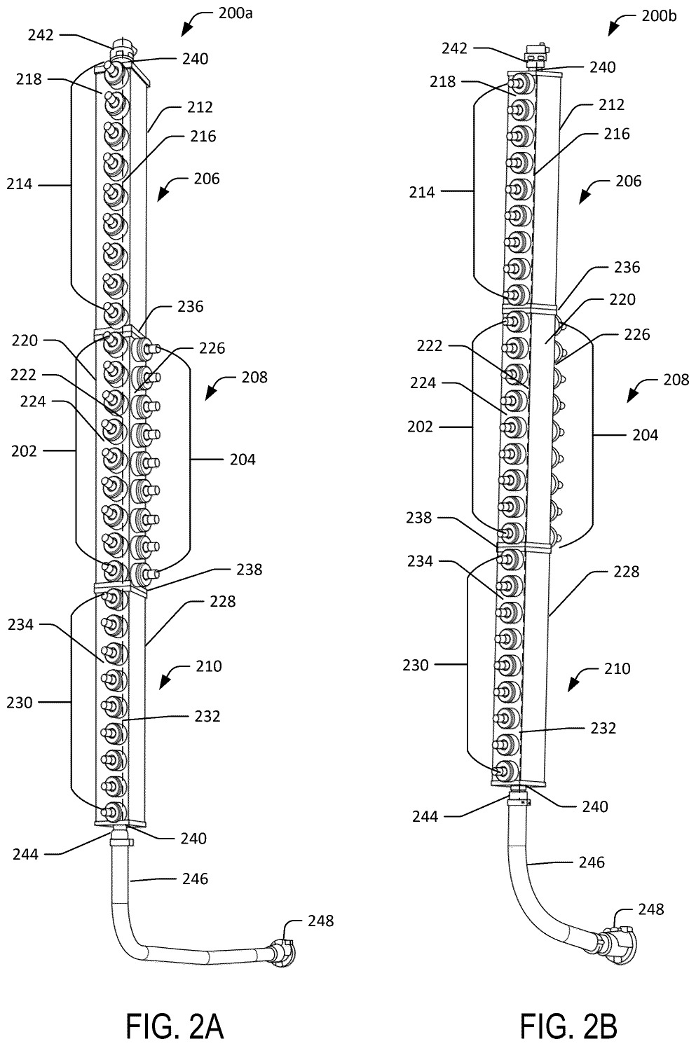

FIGS. 2A and 2B illustrate examples of a liquid manifold 200 in accordance with this disclosure. FIG. 2A illustrates a liquid manifold 200a having a plurality of second liquid connectors 202 and a plurality of third liquid connectors 204 disposed on perpendicular planes. FIG. 2B illustrates a liquid manifold 200b having the second liquid connectors 202 and the third liquid connectors 204 disposed on opposite plane. The liquid connectors may be quick-disconnect fittings, tube or pipe fittings, hose fittings (e.g., barbed fittings), pieces of tubing, or any other fluid transfer devices or fittings.

The liquid manifold 200a and the liquid manifold 200b both have a first portion 206, a second portion 208, and a third portion 210. The first portion 206 includes a first tubular body 212 (e.g., a square tube) and a plurality of first liquid connectors 214. The first tubular body 212 has a first longitudinal axis 216 (e.g., through a center of the tube) and a first external surface 218 (e.g., an external face of the tube). The first tubular body 212 forms a first cavity (e.g., an interior of the tube) that defines the first longitudinal axis 216.

The first liquid connectors 214 are disposed on the first external surface 218 and through the first tubular body 212 such that they communicate with the first cavity. The first liquid connectors 214 are disposed in a linear array that is parallel to the first longitudinal axis 216.

The second portion 208 includes a second tubular body 220 (e.g., a square tube), the second liquid connectors 202 and the third liquid connectors 204. The second tubular body 220 has a second longitudinal axis 222 (e.g., through a center of the tube), a second external surface 224 (e.g., an external face of the tube), and a third external surface 226 (e.g., another external face of the tube). The second tubular body 220 forms a second cavity (e.g., an interior of the tube) that defines the second longitudinal axis 222.

The second liquid connectors 202 are disposed on the second external surface 224 and through the second tubular body 220 such that they communicate with the second cavity. The second liquid connectors 202 are disposed in a linear array that is parallel to the second longitudinal axis 222.

The third liquid connectors 204 are disposed on the third external surface 226 and through the second tubular body 220 such that they also communicate with the second cavity. The third liquid connectors 204 are also disposed in a linear array that is parallel to the second longitudinal axis 222.

The third portion 210 includes a third tubular body 228 (e.g., a square tube) and a plurality of fourth liquid connectors 230. The third tubular body 228 has a third longitudinal axis 232 (e.g., through a center of the tube) and a fourth external surface 234 (e.g., an external face of the tube). The third tubular body 228 forms a third cavity (e.g., an interior of the tube) that defines the third longitudinal axis 232.

The fourth liquid connectors 230 are disposed on the fourth external surface 234 and through the third tubular body 228 such that they communicate with the third cavity. The fourth liquid connectors 230 are disposed in a linear array that is parallel to the third longitudinal axis 232.

An end of the first portion 206 and an end of the second portion 208 are connected such that the first longitudinal axis 216 is parallel to the second longitudinal axis 222. The first portion 206 is connected to the second portion 208 via a first rotating fitting 236 disposed between the ends of the first portion 206 and the second portion 208. An end of the second portion 208 and an end of the third portion 210 are connected such that the second longitudinal axis 222 is parallel to the third longitudinal axis 232. The second portion 208 is connected to the third portion 210 via a second rotating fitting 238 disposed between the ends of the second portion 208 and the third portion 210. For example, the rotating fittings may be directly attached to the tubular bodies (e.g., secured within the respective cavities), or the rotating fittings may be attached to end caps disposed on ends of the tubular bodies.

The first rotating fitting 236 may be configured to allow a liquid to transfer between the first cavity and the second cavity. The first rotating fitting 236 is configured to allow relative motion between the first portion 206 and the second portion 208 about a first rotation axis of the first rotating fitting 236 that is parallel to the first longitudinal axis 216 and the second longitudinal axis 222.

The second rotating fitting 238 may be configured to allow the liquid to transfer between the second cavity and the third cavity. The second rotating fitting 238 is configured to allow relative motion between the second portion 208 and the third portion 210 about a second rotation axis of the second rotating fitting 238 that is parallel to the second longitudinal axis 222 and the third longitudinal axis 232. The first rotating fitting 236 and the second rotating fitting 238 may be rotating bulkheads, swivel liquid connectors, rotating unions, or other rotating connectors or fittings.

The rotation axes may be at centers of the respective rotating fittings. Furthermore, the first rotation axis may be colinear with the second rotation axis. The first and second rotation axes may be colinear with the longitudinal axes or offset therefrom. Also, the rotating fittings may restrict relative motion about other degrees of freedom (e.g., keep the relative portions from separating).

The first rotating fitting 236 and the second rotating fitting 238 enable the liquid manifold 200 to assume two configurations (e.g., via rotation of the second portion 208 relative to the first portion 206 and the second portion 208). In the first configuration, the second external surface 224 is parallel with the first external surface 218 and the third external surface 226. The second liquid connectors 202 are configured such that they are colinear with the first liquid connectors 214 and the third liquid connectors 204 in the first configuration. In the second configuration, the third external surface 226 is parallel with the first external surface 218 and the third external surface 226. The third liquid connectors 204 are configured such that they are offset in a dimension relative to the first liquid connectors 214 and the third liquid connectors 204 in the second configuration (e.g., inbound when installed in the server rack 100 to accommodate a thinner server).

The third external surface 226 may be perpendicular to, or have its normal axis 90 degrees from a normal axis of, the second external surface 224 (e.g., as in liquid manifold 100a). In other implementations, the third external surface 226 may be opposite to, or have its normal axis that is 180 degrees from the normal axis of, the second external surface 224 (e.g., as in liquid manifold 200b). If the second tubular body 220 is a square tube, then the second external surface 224 and the third external surface 226 may be adjacent sides of the square tube (e.g., as in liquid manifold 200a). Alternatively, the second external surface 224 and the third external surface 226 may be opposite sides of the square tube (e.g., as in liquid manifold 200b).

Accordingly, the liquid manifold 200a may be switched between the two configurations via a 90 degree rotation of the second portion 208 relative to the first portion 206 and the third portion 210. The liquid manifold 200b may be switched between the two configurations via a 180 degree rotation of the second portion 208 relative to the first portion 206 and the third portion 210.

The liquid manifold 200 also contains two liquid ports 240. The liquid ports 240 allow liquid to enter or exit the liquid manifold 200. The liquid ports 240 are disposed on opposite ends of the first tubular body 212 and the third tubular body 228 (e.g., away from the first rotating fitting 236 and the second rotating fitting 238). The liquid ports 240 may be open ends of the respective tubular bodies or connected to end plates attached to ends of the respective tubular bodies.

The liquid manifold 100a and the liquid manifold 100b are both examples of a single side (e.g., influent or effluent) of a system for the server rack 100. To form the other side, the liquid manifold 200 may be flipped such that the first portion 206 is below the second portion 208. This is because the influent and effluent sides are mirrors of each other. The two liquid ports 240 allow the liquid manifold 200 to be used as both influent and effluent plumbing. To do so, one of the liquid ports 240 may be plugged (e.g., a top one) and the opposite liquid port 240 used to connect the liquid manifold 200 to supply or return feeds.

A complete liquid manifold 200 may comprise the first portion 206, the second portion 208, and the third portion 210 connected together, a plug 242 in one of the liquid ports 240, a hose fitting 244 in another of the liquid ports 240, a hose 246 connected to the hose fitting 244, and a connection fitting 248 on another end of the hose 246 (e.g., to attach to a supply feed or a return feed). It should be noted that the one of the liquid ports 240 may also be used to feed another liquid manifold 200 (e.g., in a different server rack 100).

### Example Rotating Fitting

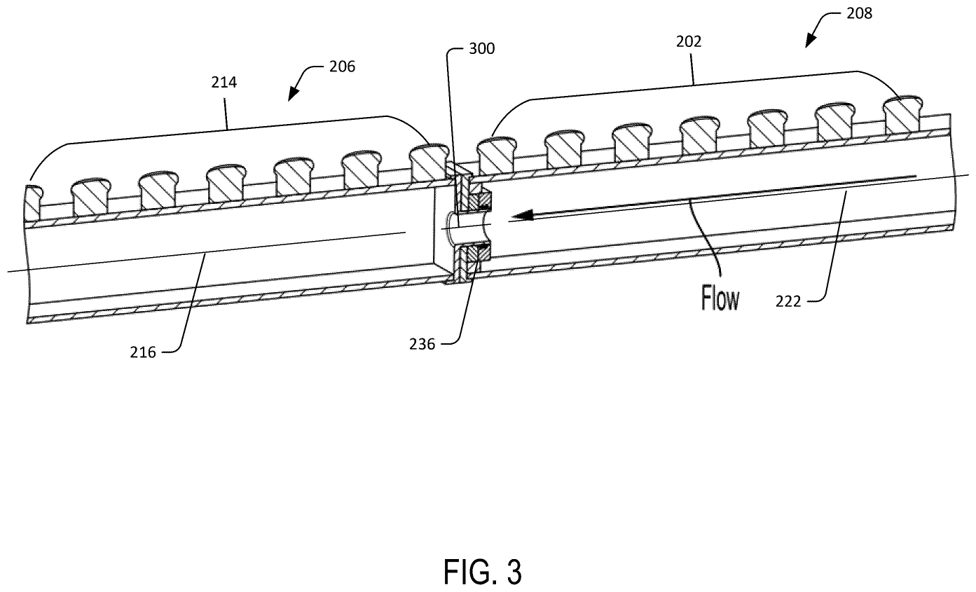

FIG. 3 illustrates an example of the first rotating fitting 236 installed between the first portion 206 and the second portion 208. The second rotating fitting 238 may be a similar structure installed between the second portion 208 and the third portion 210. As discussed above, the first rotating fitting 236 is any piece of hardware or assembly that connects the first portion 206 to the second portion 208 and enables relative rotation therebetween. Although not required, the first rotating fitting 236 may also enable fluid transfer between the first cavity and the second cavity (as illustrated) via one or more holes.

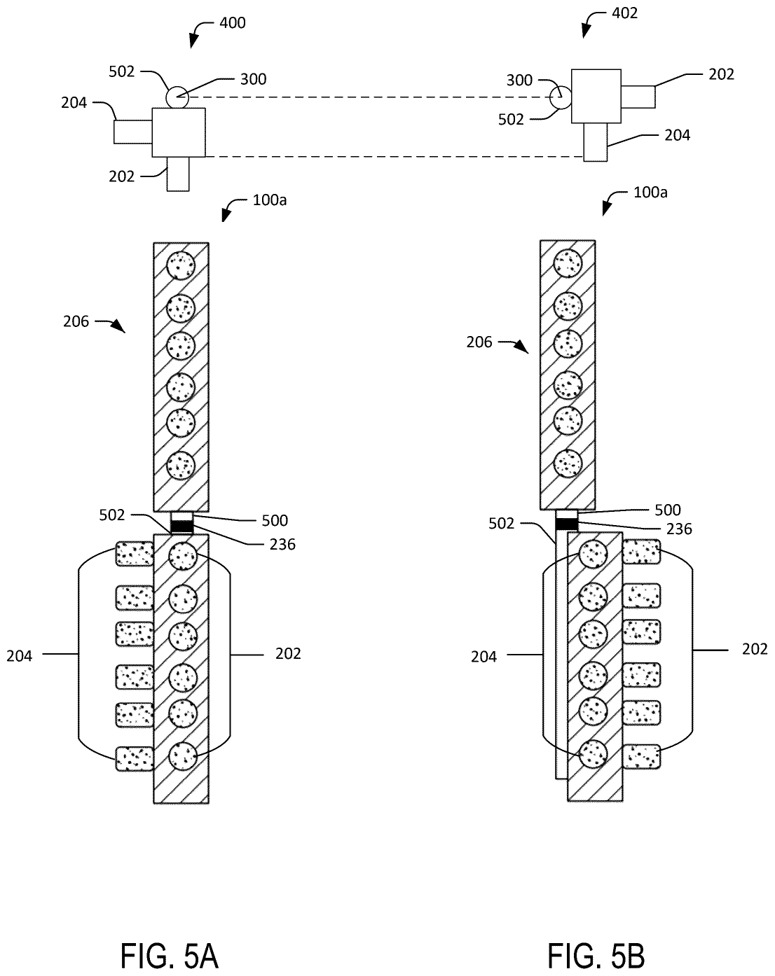

In the illustrated example, the first rotating fitting 236 is installed such that the first rotation axis 300 is colinear with the first longitudinal axis 216 and the second longitudinal axis 222. Thus, the second portion 208 may rotate about a center of the second tubular body 220. The illustrated example may work well when the second liquid connectors 202 are opposite the third liquid connectors 204 (e.g., as in liquid manifold 200b). In other implementations, the first rotation axis 300 may be offset from the first longitudinal axis 216 and/or the second longitudinal axis 222 (e.g., to enable an off-center rotation of the second portion 208). FIGS. 5A and 5B illustrate an example of an off-center rotation of the second portion 208.

The flow may go either way through the first rotating fitting 300. Furthermore, it should be noted that the liquid connectors interface with the respective cavities although that interface is not shown.

### Example System Using Opposite Second and Third External Surfaces

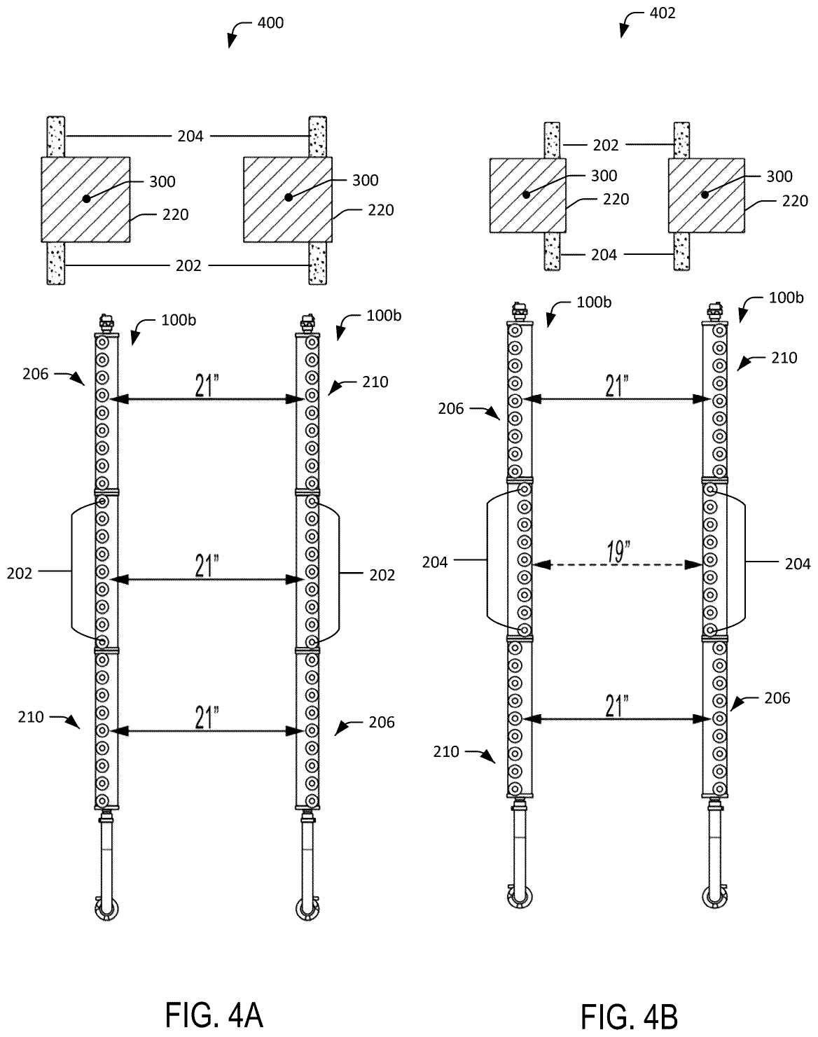

FIGS. 4A and 4B illustrate an example of a system using two liquid manifolds 100b in the two configurations. FIG. 4A illustrates the two liquid manifolds 100b in the first configuration 400 where the second liquid connectors 202 are colinear with the first liquid connectors 214 and the fourth liquid connectors 230. FIG. 4B illustrates the two liquid manifolds 100b in the second configuration 402 where the third liquid connectors 204 are offset from the first liquid connectors 214 and the fourth liquid connectors 230 (e.g., inbound left/right). The upper portion of FIGS. 4A and 4B illustrate top-down views of the second portions 208 in the respective configurations. The first configuration 400 may enable the second portions 208 to interface with 21 inch servers, while the second configuration 402 may enable the second portions 208 to interface with 19 inch servers. Other widths of servers (e.g., 23 inch nominal) may be serviced without departing from the scope of this disclosure.

In order to enable the configurations, the liquid connectors may be off-center of their respective external surfaces. For example, the first liquid connectors 214 and the fourth liquid connectors 230 may be pushed to one side as shown. The second liquid connectors 202 and the third liquid connectors 204 may be disposed towards a same side of the second tubular body 220 (albeit on opposite surfaces).

As discussed above, the left/right or influent/effluent sides of the system may be mirrored. Accordingly, the first portion 206, the second portion 208, and the third portion 210 may be fabricated and assembled the same way for both sides and one inverted to make an opposite side (as illustrated). Alternatively, if the ends of the first portion 206 and the third portion 210 are similar (e.g., the liquid ports 240 are similar to structures that the rotating fittings attach to), the first portion 206 and the third portion 210 may be flipped to form the opposite side (the second portion 208 may remain in the same configuration).

Between the first configuration 400 and the second configuration 402, the second portions 208 (e.g., left/right or influent/effluent) are rotated 180 degrees relative to the first portions 206 and the third portions 210. Doing so enables a switch between the second liquid connectors 202 and the third liquid connectors 204 to be co-planar with the first liquid connectors 214 and the fourth liquid connectors 230.

### Example System Using Perpendicular Second and Third External Surfaces

FIGS. 5A and 5B illustrate an example of the liquid manifold 100a in the first configuration 400 and the second configuration 402. FIG. 5A illustrates the liquid manifold 100a in the second configuration 402 where the third liquid connectors 204 are offset from the first liquid connectors 214. FIG. 5B illustrates the liquid manifold 100a in the first configuration 400 where the second liquid connectors 202 are colinear with the first liquid connectors 214. The upper portion of FIGS. 5A and 5B illustrate top-down views of the second portions 208 in the respective configurations. The first configuration 400 may enable the second portions 208 to interface with first width (e.g., 21 inch) servers, while the second configuration 402 may enable the second portions 208 to interface with second width (e.g., 19 inch) servers.

Between the first configuration 400 and the second configuration 402, the second portion 208 is rotated 90 degrees relative to the first portion 206. Doing so enables a switch between the second external surface 224 and the third external surface 226 to be parallel with the first external surface 218.

In the illustrated example, the first rotation axis 300 is not within a cross-section of the first tubular body 212 or the second tubular body 220. Instead, the first rotation axis 300 is within a cross-section of a first tube 500 and a second tube 502 attached to the first tubular body 212 and the second tubular body 220, respectively. To enable the off-center rotation, the first rotating fitting 236 interfaces with ends of the first tube 500 and the second tube 502 (the first tube 500 and the second tube 502 may be hollow tubes). The first tube 500 may include a first tube cavity that interfaces with the first cavity and the second tube 502 may include a second tube cavity that interfaces with the second cavity to provide liquid flow therebetween.

In some implementations, the tubular bodies may have a large enough cross section that the first rotating fitting 236 may be within the cross-section of the tubular bodies. Regardless of where the first rotating fitting 236 is disposed relative to the tubular bodies, a 90 degree rotation of the second portion 208 relative to the first portion 206 (e.g., via the first liquid connector 214) causes a switch between the second liquid connectors 202 and the third liquid connectors 204 to be oriented similarly to the first liquid connectors 214 (e.g., facing a same direction).

It should be noted that the third liquid connectors 204 are offset in two dimensions. This is because a plane of the second external surface 224 is closer to the first rotation axis 300 than a plane of the third external surface 226. To compensate, the third liquid connectors 204 may be longer or otherwise spaced out from the third external surface 226. In other implementations (e.g., depending upon respective external surfaces and where the first rotation axis 300 is), the second liquid connectors 204 may need to be longer or spaced out.

It should also be noted that the third portion 210 may not exist in some implementations (e.g., as illustrated). For example, the second portion 208 may have a liquid port 240 on the opposite side of the first rotating fitting 236. The liquid port 240 may be plugged or have the associated plumbing attached thereto. Alternatively, the second rotating fitting 238 may exist without the third portion and the plug or associated plumbing attached thereto. Conversely, more portions may exist without departing from the scope of this disclosure.

### EXAMPLES

Example 1: A liquid manifold for providing a liquid to or from a plurality of servers within a server rack, the liquid manifold comprising: a first portion including: a first tubular body including: a first cavity that extends along a first longitudinal axis; and a first external surface; and a plurality of first liquid connectors: disposed on the first external surface; communicating with the first cavity; and arranged in a first linear array parallel to the first longitudinal axis; a second portion including: a second tubular body including: a second cavity that extends along a second longitudinal axis; and a second external surface and a third external surface; and a plurality of second liquid connectors: disposed on the second external surface; communicating with the second cavity; and arranged in a second linear array parallel to the second longitudinal axis; and a plurality of third liquid connectors: disposed on the third external surface; communicating with the second cavity; and arranged in a third linear array parallel to the second longitudinal axis; and a first rotating fitting: connecting an end of the first portion and an end of the second portion; and configured to allow relative rotation between the first portion and the second portion about a first rotation axis of the first rotating fitting that is parallel to the first longitudinal axis and the second longitudinal axis.

Example 2: The liquid manifold of example 1, wherein the liquid connectors are quick-disconnect fittings.

Example 3: The liquid manifold of example 1 or 2, wherein the first portion or the second portion includes a liquid port disposed on an end of the first portion or the second portion configured to allow the liquid to enter or exit the liquid manifold.

Example 4: The liquid manifold of example 1, 2, or 3, wherein: the second external surface has a second normal axis; the third external surface has a third normal axis; and the second normal axis is perpendicular to the third normal axis.

Example 5: The liquid manifold of example 1, 2, or 3, wherein: the second external surface has a second normal axis; the third external surface has a third normal axis; and the second normal axis is opposite to the third normal axis.

Example 6: The liquid manifold of any preceding example, wherein the first rotating fitting is configured such that: a first configuration allows the first external surface to be parallel with the second external surface; and a second configuration allows the first external surface to be parallel with the third external surface.

Example 7: The liquid manifold of example 6, wherein: in the first configuration, the first linear array is colinear with the second linear array; and in the second configuration, the third linear array is offset from the first linear array in at least one dimension.

Example 8: The liquid manifold of example 7, wherein the offset is an inch.

Example 9: The liquid manifold of any preceding example, wherein the first rotating fitting is disposed within a cross-section of the first tubular body and a cross-section of the second tubular body.

Example 10: The liquid manifold of any preceding example, wherein the first rotating fitting is disposed outside of a cross-section of the second tubular body.

Example 11: The liquid manifold of example 10, wherein the first rotating fitting is attached to a tube attached to the second tubular body.

Example 12: The liquid manifold of example 11, wherein a tube cavity of the tube communicates with the second cavity.

Example 13: The liquid manifold of any preceding example, further including: a third portion including: a third tubular body having: a third cavity that extends along a third longitudinal axis; and a fourth external surface; and a plurality of fourth liquid connectors: disposed on the fourth external surface; communicating with the third cavity; and arranged in a fourth linear array parallel to the third longitudinal axis; and a second rotating fitting: connecting an end of the second portion and an end of the third portion such that the first longitudinal axis and the second longitudinal axis are parallel to the third longitudinal axis; and configured to allow relative rotation between the second portion and the third portion about a second rotation axis of the second rotating fitting that is parallel to the first longitudinal axis, the second longitudinal axis, and the third longitudinal axis.

Example 14: The liquid manifold of example 13, wherein the first rotation axis is colinear with the second rotation axis.

Example 15: The liquid manifold of example 13 or 14, wherein the first linear array is colinear with the fourth linear array.

Example 16: The liquid manifold of example 13, 14, or 15, wherein the first portion and the third portion include respective liquid ports on ends of the first portion and the third portion configured to allow the liquid to enter or exit from the liquid manifold.

Example 17: The liquid manifold of example 16, wherein one of the liquid ports is plugged.

Example 18: A system comprising: a first liquid manifold for providing a liquid to a plurality of servers within a server rack; and a second liquid manifold for providing the liquid from the plurality of servers, each of the first liquid manifold and the second liquid manifold including: a first portion including: a first tubular body including: a first cavity that extends along a first longitudinal axis; and a first external surface; and a plurality of first liquid connectors: disposed on the first external surface; communicating with the first cavity; and arranged in a first linear array parallel to the first longitudinal axis; a second portion including: a second tubular body including: a second cavity that extends along a second longitudinal axis; and a second external surface and a third external surface; a plurality of second liquid connectors: disposed on the second external surface; communicating with the second cavity; and arranged in a second linear array parallel to the second longitudinal axis; and a plurality of third liquid connectors: disposed on the third external surface; communicating with the second cavity; and arranged in a third linear array parallel to the second longitudinal axis; and a first rotating fitting: connecting an end of the first portion and an end of the second portion such that the first longitudinal axis is parallel to the second longitudinal axis; and configured to allow relative rotation between the first portion and the second portion about a first rotation axis of the first rotating fitting that is parallel to the first longitudinal axis and the second longitudinal axis.

Example 19: The system of example 18, wherein each first rotating fitting is configured such that: a first configuration of the first liquid manifold and the second liquid manifold allows the first liquid connectors to be colinear with the second liquid connectors; and a second configuration of the first liquid manifold and the second liquid manifold allows the third liquid connectors to be offset in at least one dimension from the first liquid connectors.

Example 20: The system of example 19, wherein: the first configuration allows the first liquid connectors and the second liquid connectors to, when mounted to the server rack, mate with twenty-one inch servers; and the second configuration allows the first liquid connectors to mate with twenty-one inch servers and the third liquid connectors to, when mounted to the server rack, mate with nineteen inch servers.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description, but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A liquid manifold for providing a liquid to or from a plurality of servers within a server rack, the liquid manifold comprising:
a first portion including:
a first tubular body including:
a first cavity that extends along a first longitudinal axis; and
a first external surface; and
a plurality of first liquid connectors:
disposed on the first external surface;
communicating with the first cavity; and
arranged in a first linear array parallel to the first longitudinal axis;
a second portion including:
a second tubular body including:
a second cavity that extends along a second longitudinal axis; and
a second external surface and a third external surface; and
a plurality of second liquid connectors:
disposed on the second external surface;
communicating with the second cavity; and
arranged in a second linear array parallel to the second longitudinal axis; and
a plurality of third liquid connectors:
disposed on the third external surface;
communicating with the second cavity; and
arranged in a third linear array parallel to the second longitudinal axis; and
a first rotating fitting:
connecting an end of the first portion and an end of the second portion; and
configured to allow relative rotation between the first portion and the second portion about a first rotation axis of the first rotating fitting that is parallel to the first longitudinal axis and the second longitudinal axis.

2. The liquid manifold of claim 1, wherein the second liquid connectors and the third liquid connectors include quick-disconnect fittings.

3. The liquid manifold of claim 1, wherein the first portion or the second portion includes a liquid port disposed on an end of the first portion or the second portion configured to allow the liquid to enter or exit the liquid manifold.

4. The liquid manifold of claim 1, wherein:
the second external surface has a second normal axis;
the third external surface has a third normal axis; and
the second normal axis is perpendicular to the third normal axis.

5. The liquid manifold of claim 1, wherein:
the second external surface has a second normal axis;
the third external surface has a third normal axis; and
the second normal axis is opposite to the third normal axis.

6. The liquid manifold of claim 1, wherein the first rotating fitting is configured such that:
a first configuration allows the first external surface to be parallel with the second external surface; and
a second configuration allows the first external surface to be parallel with the third external surface.

7. The liquid manifold of claim 6, wherein:
in the first configuration, the first linear array is colinear with the second linear array; and
in the second configuration, the third linear array is offset from the first linear array in at least one dimension.

8. The liquid manifold of claim 7, wherein the offset is an inch.

9. The liquid manifold of claim 1, wherein the first rotating fitting is disposed within a cross-section of the first tubular body and a cross-section of the second tubular body.

10. The liquid manifold of claim 1, wherein the first rotating fitting is disposed outside of a cross-section of the second tubular body.

11. The liquid manifold of claim 10, wherein the first rotating fitting is attached to a tube attached to the second tubular body.

12. The liquid manifold of claim 11, wherein a tube cavity of the tube communicates with the second cavity.

13. The liquid manifold of claim 1, further including:
a third portion including:
a third tubular body having:
a third cavity that extends along a third longitudinal axis; and
a fourth external surface; and
a plurality of fourth liquid connectors:
disposed on the fourth external surface;
communicating with the third cavity; and
arranged in a fourth linear array parallel to the third longitudinal axis; and
a second rotating fitting:
connecting an end of the second portion and an end of the third portion such that the first longitudinal axis and the second longitudinal axis are parallel to the third longitudinal axis; and
configured to allow relative rotation between the second portion and the third portion about a second rotation axis of the second rotating fitting that is parallel to the first longitudinal axis, the second longitudinal axis, and the third longitudinal axis.

14. The liquid manifold of claim 13, wherein the first rotation axis is colinear with the second rotation axis.

15. The liquid manifold of claim 13, wherein the first linear array is colinear with the fourth linear array.

16. The liquid manifold of claim 13, wherein the first portion and the third portion include respective liquid ports on ends of the first portion and the third portion configured to allow the liquid to enter or exit from the liquid manifold.

17. The liquid manifold of claim 16, wherein one of the liquid ports is plugged.

18. A system comprising:
a first liquid manifold for providing a liquid to a plurality of servers within a server rack; and
a second liquid manifold for providing the liquid from the plurality of servers, each of the first liquid manifold and the second liquid manifold including:
a first portion including:
a first tubular body including:
a first cavity that extends along a first longitudinal axis; and
a first external surface; and
a plurality of first liquid connectors:
disposed on the first external surface;
communicating with the first cavity; and
arranged in a first linear array parallel to the first longitudinal axis;
a second portion including:
a second tubular body including:
a second cavity that extends along a second longitudinal axis; and
a second external surface and a third external surface;
a plurality of second liquid connectors:
disposed on the second external surface;
communicating with the second cavity; and
arranged in a second linear array parallel to the second longitudinal axis; and
a plurality of third liquid connectors:
disposed on the third external surface;
communicating with the second cavity; and
arranged in a third linear array parallel to the second longitudinal axis; and
a first rotating fitting:
connecting an end of the first portion and an end of the second portion such that the first longitudinal axis is parallel to the second longitudinal axis; and
configured to allow relative rotation between the first portion and the second portion about a first rotation axis of the first rotating fitting that is parallel to the first longitudinal axis and the second longitudinal axis.

19. The system of claim 18, wherein each first rotating fitting is configured such that:
a first configuration of the first liquid manifold and the second liquid manifold allows the first liquid connectors to be colinear with the second liquid connectors; and
a second configuration of the first liquid manifold and the second liquid manifold allows the third liquid connectors to be offset in at least one dimension from the first liquid connectors.

20. The system of claim 19, wherein:
the first configuration allows the first liquid connectors and the second liquid connectors to, when mounted to the server rack, mate with twenty-one inch servers; and
the second configuration allows the first liquid connectors to mate with twenty-one inch servers and the third liquid connectors to, when mounted to the server rack, mate with nineteen inch servers.
